(19) United States
(12) Patent Application Publication
(10) Pub. No.: US 2006/0169922 A1
(43) Pub. Date: Aug. 3, 2006

(54) Ion implant ion beam parallelism and direction integrity determination and adjusting

(76) Inventors: Shengwu Chang, South Hamilton, MA (US); Joseph C. Olson, Beverly, MA (US); Damian Brennan, Gloucester, MA (US)

Correspondence Address: HOFFMAN, WARNICK & D'ALESSANDRO LLC, 75 STATE STREET, 14TH FLOOR, ALBANY, NY, 12207, US

(21) Appl. No.: 11/246,410

(22) Filed: Oct. 7, 2005

Related U.S. Application Data
(60) Provisional application No. 60/617,117, filed on Oct. 8, 2004.

(51) Int. Cl. H01J 37/08

(52) U.S. Cl. 250/492.21

(57) ABSTRACT

A system, method and program product for controlling parallelism and/or direction integrity of an ion beam generated by an ion implanter system are disclosed. The invention utilizes multiple faraday cups to measure a profile of at least a portion of the ion beam. The results of the measurement are then processed to determine parallelism and/or direction integrity of the ion beam. The results of the parallelism and/or direction integrity determination are then used to adjust the ion implanter system operating parameters to control parallelism and the direction of the ion beam.

### CROSS-REFERENCE TO RELATED APPLICATIONS

The current application claims the benefit of co-pending U.S. Provisional Application No. 60/617,117 filed Oct. 8, 2004, which is hereby incorporated herein by reference.

### BACKGROUND OF THE INVENTION

1. Technical Field

The present invention relates generally to ion implantation, and more particularly, to a system, method and program product for determining and adjusting parallelism and the direction of an ion beam.

2. Related Art

Controlling the direction and/or parallelism of an ion beam is important for the proper operation of various different types of devices and processes. Ion implantation is a standard technique for introducing conductivity altering impurities into, or doping, semiconductor wafers. A typical ion implantation process uses an energetic ion beam to introduce impurities into semiconductor wafers. As is well known, introducing the impurities at a uniform depth and dose into the wafers is important to ensure that semiconductor devices being formed operate properly.

The depth at which impurities are implanted depends in part upon the angle of an ion beam relative to the crystal structure of the semiconductor. Therefore, it is important to control the direction and/or parallelism of the ion beam during implantation to maintain a desired angle (i.e., desired direction) of the ion trajectories relative to a wafer's crystal structure, particularly when scanning the ion beam across a wafer surface.

FIG. 1 shows schematically, in three dimensions, a conventional implantation of an ion beam into a wafer. Z-Axis and X-Axis constitute a horizontally ion beam scan plane. An ion beam is delivered (desirably) parallel to the Z-Axis and strikes the planar surface of the wafer. The X-Axis is horizontally perpendicular to the Z-Axis. The ion beam is scanned back and forth along a scan path parallel to the X-Axis. The Y-Axis is vertically perpendicular to the ion beam scan plane (i.e., the XZ-coordinate plane). The wafer is scanned up and down along another scan path parallel to the Y-Axis by moving the wafer up and down.

When an ion beam is scanned across a wafer, the angle of incidence of the ions relative to a desired direction of the ion beam can vary from one end of the scan path to the other. Since both the direction and the parallelism of the ion beam affect the angle of incidence that each ion strikes the wafer, determining and controlling the direction and parallelism of the ion beam is useful in ensuring that the doped semiconductor wafer has desired characteristics. For example, if a scanned ion beam is known to have components at opposite ends of the scan line that are not sufficiently parallel to a desired direction, portions of the implantation system, such as an angle corrector magnet, can be adjusted to make the ion beam components more parallel to the desired direction. Even when a fixed ion beam is utilized and the wafer is mechanically scanned, measurement and control of ion beam parallelism and direction are needed to ensure that the ions in the ion beam are incident on the wafer at a desired angle of incidence over the area of the ion beam.

It is well known in the art that a scanned ion beam includes a group of spot ion beams that represent the scanned ion beam at each specific time point, as shown by FIG. 2. Each spot ion beam may have a different angle of incidence, i.e., a spot ion beam angle, relative to the desired direction. A global ion beam angle spread is defined as the difference between the maximum spot ion beam angle and the minimum spot ion beam angle. A global ion beam angle mean is defined as an average of the group of spot ion beam angles. If the global ion beam angle spread equals zero, the group of spot ion beams are considered parallel to each other.

Within each spot ion beam, ion trajectories still reach the wafer in various angles of incidence, i.e., ion trajectory angle. FIG. 3 shows a spot ion beam including a group of ion trajectories. A local ion beam angle spread is defined as the difference between the maximum ion trajectory angle and the minimum ion trajectory angle. A local ion beam angle mean is defined as an average of the group of ion trajectory angles. If the local ion beam angle spread equals zero, the spot ion beam is considered locally parallel, i.e., the group of ion trajectories are parallel to each other. If the local ion beam angle mean equals zero, the spot ion beam is considered in the desired direction.

FIGS. 4-7 show ion beams that are globally parallel, but have different local ion beam angle distributions. In FIG. 4, the global ion beam angle spread and the global ion beam angle mean are zero because all the local ion beam angle means are the same and in the desired direction. However, local ion beam angle spreads are different among individual spot ion beams. This is not desirable for producing a uniform implantation. In FIG. 5, the global ion beam angle spread and the global ion beam angle mean are zero and all the local ion beam angle spreads are also the same. This is a desirable ion beam for producing a uniform implantation. In FIG. 6, all the local ion beam angle spreads are the same and are smaller than those of FIG. 5. This is a more desirable ion beam for producing a uniform implantation. Finally, in FIG. 7, all the local ion beam angle spreads and local ion beam angle means are zero. This ion beam is both locally parallel and in the desired direction and thus is the most desirable ion beam for producing a uniform implantation.

Efforts have been made to control parallelism and the direction of an ion beam. For example, Olson et al. (U.S. Pat. No. 6,791,094) has invented a method and apparatus for determining ion beam parallelism and direction. The method of Olson et al. detects the changes in an ion beam profile measured at a position when the scanned ion beam is shadowed by an object. The Olson et al. method, however, only controls global parallelism/direction integrity of an ion beam, i.e., whether the global ion beam angle spread (or the global ion beam angle mean) is zero. Olson et al. do not determine and control local parallelism and direction integrity of an ion beam. As discussed above, there is a need to control the local ion beam parallelism/direction integrity to produce a properly operating device on a wafer.

### SUMMARY OF THE INVENTION

A system, method and program product for controlling parallelism and/or direction integrity of an ion beam generated by an ion implanter system are disclosed. The invention utilizes multiple faraday cups to measure a profile of at least a portion of the ion beam. The results of the measurement are then processed to determine parallelism and/or direction integrity of the ion beam including local parallelism and direction integrity. The results of the parallelism and/or direction integrity determination are then used to adjust the ion implanter system operating parameters to control parallelism and the direction of the ion beam.

A first aspect of the invention is directed to a method for determining at least one of parallelism and direction integrity of an ion beam for implanting into a work piece, the method comprising steps of: obtaining an ion beam profile at a plurality of positions in a lateral line across a desired direction of the ion beam; and determining parallelism and direction integrity of the ion beam based on the ion beam profile and the plurality of positions.

A second aspect of the invention is directed to a system for at least one of determining parallelism and direction integrity of an ion beam for implanting into a work piece, the system comprising: a measurer for obtaining an ion beam profile at a plurality of positions in a lateral line across a desired direction of the ion beam; and a determinator for determining at least one of parallelism and direction integrity of the ion beam based on the ion beam profile and the plurality of positions.

A third aspect of the invention is directed to a program product stored on a computer-readable medium, which when executed, enables a computer infrastructure to determine at least one of parallelism and direction integrity of an ion beam for implanting into a work piece, the program product comprising computer program code for enabling the computer infrastructure to obtain an ion beam profile at a plurality of positions in a lateral line across a desired direction of the ion beam, and to determine at least one of parallelism and direction integrity of the ion beam based on the ion beam profile and the plurality of positions.

A fourth aspect of the invention is directed to a method of generating a system for determining at least one of parallelism and direction integrity of an ion beam for implanting into a work piece, the method comprising: providing a computer infrastructure operable to obtain an ion beam profile at a plurality of positions in a lateral line across a desired direction of the ion beam, and to determine at least one of parallelism and direction integrity of the ion beam based on the ion beam profile and the plurality of positions.

The foregoing and other features of the invention will be apparent from the following more particular description of embodiments of the invention.

### BRIEF DESCRIPTION OF THE DRAWINGS

The embodiments of this invention will be described in detail, with reference to the following figures, wherein like designations denote like elements, and wherein:

FIG. 1 shows a three-dimensional view of an ion beam implantation, according to prior art.

FIG. 2 shows a two-dimensional view of an ion beam that includes a group of spot ion beams, according to prior art.

FIG. 3 shows a two-dimensional view of a spot ion beam that includes a group of ion trajectories, according to prior art.

FIGS. 4-7 show four ion beams that are all globally parallel, but have different local ion beam angle distributions, according to prior art.

FIG. 8 shows a schematic view of an ion beam implanter system according to one embodiment of the invention.

FIG. 9 shows a schematic view of an illustrative embodiment of a measurer according to one embodiment of the invention.

FIG. 10 shows a three-dimensional view of the exemplary embodiment of the measurer of FIG. 9.

FIG. 11 shows a schematic view of a first method for a faraday cup to measure an ion beam profile, according to one embodiment of the invention.

FIG. 12 shows a schematic view of a second method for a faraday cup to measure an ion beam profile, according to one embodiment of the invention

FIG. 13 shows an exemplary spot ion beam profile, according to the invention.

FIG. 14 shows a block diagram of an illustrative controller, according to the invention.

FIG. 15 shows a flow diagram of one embodiment of the operation of an ion beam parallelism/direction controller, according to the invention.

FIG. 16 shows schematically one embodiment of the numbers and positions of sampling faraday cups and traveling faraday cup stops, according to the invention.

FIG. 17 shows an exemplary pair of ion beam profiles that are measured by the sampling faraday cups in a sampling line and by the traveling faraday cup in a traveling line.

FIG. 18 shows a method to determine an angle of incidence, according to one embodiment of the invention.

### DETAILED DESCRIPTION

1. Definitions

In the above and following disclosure, the listed words (phrases) are defined as follows:

An angle of incidence is the angle between an ion beam or an ion trajectory and the desired direction of the ion beam that is parallel to a Z-Axis in an ion beam scan plane.

A direction of an ion beam is the overall orientation of the ion beam relative to the desired direction of the ion beam that is parallel to a Z-Axis.

A direction of a spot ion beam is the orientation of the spot ion beam relative to the desired direction of the ion beam that is parallel to a Z-Axis.

A global direction integrity is a measure of the degree that the direction of an ion beam is parallel to the desired direction of the ion beam. A global direction integrity is inherently a measure of global parallelism because only a globally parallel ion beam can be parallel to the desired direction.

An ion beam scan plane is a horizontal XZ-coordinate plane in which an ion beam is delivered parallel to the Z-Axis and scanned back and forth along a scan path parallel to the X-Axis.

A global ion beam angle mean is the average of the group of spot ion beam angles.

A global ion beam angle spread is one half of the difference between the maximum spot ion beam angle and the minimum spot ion beam angle.

A global parallelism of an ion beam is the relative degree of collimation of the ion beam, or a measure of convergence or divergence of two or more portions (spot ion beams) of a stationary or scanned ion beam. A global parallelism is inherently a measure of global direction integrity because only a globally parallel ion beam can be parallel to its desired direction.

A local ion beam angle spread is one half of the difference between the maximum ion trajectory angle and the minimum ion trajectory angle.

A local ion beam angle mean (also named spot ion beam angle) is the average of the group of ion trajectory angles.

A local direction integrity is a measure of the degree that the direction of a spot ion beam is parallel to the desired direction of the spot ion beam.

A local parallelism is the relative degree of collimation of a spot ion beam, or a measure of convergence or divergence of ion trajectories of the spot ion beam.

A position is a lateral position along an X-Axis.

A spot ion beam is the trajectories of an ion beam at a specific time point.

A scan path is a range in an X-Axis within which an ion beam is scanned.

2. Ion Implanter System Overview

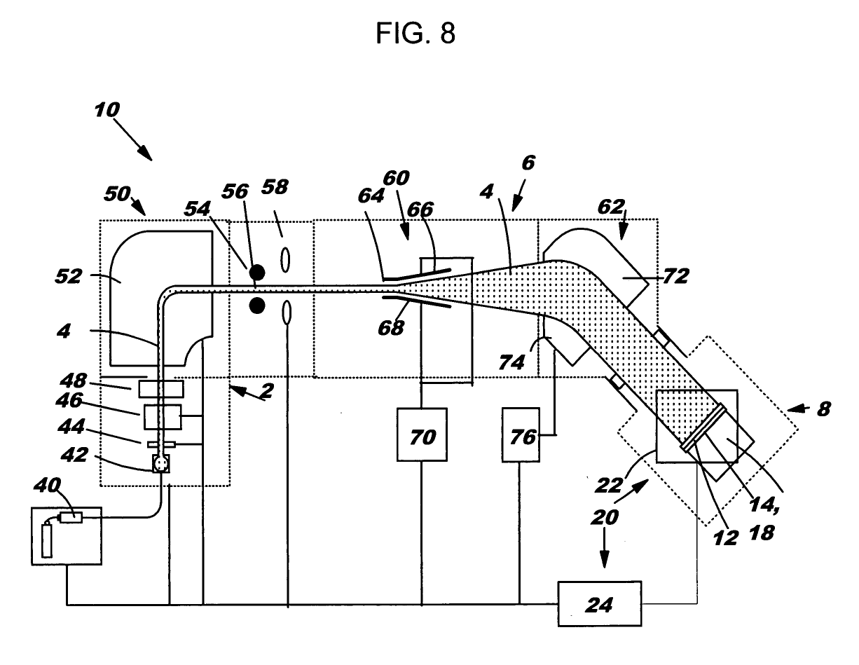

With reference to the accompanying drawings, FIG. 8 illustrates an exemplary ion implanter system 10, which may be used in the present invention. Implanter system 10 includes an ion beam generating sub-system 2 for generating and transmitting an ion beam 4, through ion beam scanning sub-system 6, to a target sub-system 8. Ion beam generating sub-system 2 may include any now known or later developed ion beam generator such as those available from Varian Semiconductor Equipment Associates. Typically, target sub-system 8 includes one or more semiconductor targets 12 (e.g., wafer) mounted to a platen 14. Characteristics of platen 14 and, hence, target 12, may be controlled by a platen drive assembly (not shown) that rotates target 12, i.e., wafer, and by a target vertical scan position controller 18 that controls the vertical position of target 8. Ion implanter system 10 may include additional components known to those skilled in the art. For example, target sub-system 8 typically includes automated wafer handling equipment for introducing wafers into ion implanter system 10 and for removing wafers after implantation, a dose measurement device, an electron flood gun, etc. It will be understood that the entire path traversed by ion beam 4 is evacuated during ion implantation.

Besides the above-described components, ion beam generating sub-system 2 may include a gas flow 40, an ion beam source 42, an extraction manipulator 44, a filter magnet 46, an acceleration/deceleration column 48, and a mass analyzer 50. Filter magnet 46 is preferably positioned in close proximity to ion beam source 42. Extraction manipulator 44 is positioned between filter magnet 46 and ion beam source 42. Acceleration/deceleration column 48 is positioned between source filter 46 and mass analyzer 50. Mass analyzer 50 may include, for example, a dipole analyzing magnet 52, a mass slit 54 having a resolving aperture 56, and an electrostatic lens 58.

Scanning sub-system 6 may include, for example, a scanner 60 and an angle corrector 62. Scanner 60, which may be an electrostatic scanner, deflects ion beam 4 to produce a scanned ion beam 4 having ion trajectories which diverge from a scan origin 64. Scanner 60 may include spaced-apart scan plates 66 and 68 responsive to a scan generator 70. Scan generator 70 generates a scan voltage waveform, such as a sawtooth, or triangular waveform, for deflecting ion beam 4 in accordance with the electric field between scan plates 66 and 68. Angle corrector 62 is designed to deflect ions in scanned ion beam 4 to have parallel ion trajectories, i.e., to focus scanned ion beam 4. In one embodiment, angle corrector 62 may include magnetic polepieces 72 that are spaced apart to define a gap, and a magnetic coil 74 that is coupled to a power supply 76. Scanned ion beam 4 passes through the gap between polepieces 72 and is deflected in accordance with a magnetic field in the gap. The magnetic field may be adjusted by varying the current through magnetic coil 74 which is provided by power supply 76.

Ion implanter system 10 may further include an ion implant ion beam control system (control system) 20. Control system 20 includes an ion beam profile measurer 22 (measurer 22) and a controller 24. Measurer 22 is positioned at or near platen 14. Measurer 22 is coupled to controller 24 to receive measurement parameters from and communicate measurement results to controller 24. Controller 24 is further coupled to ion beam generating sub-system 2 and ion beam scanning sub-system 6 to set up/adjust system parameters. Specifically, controller 24 is coupled to, inter alia, extraction manipulator 44, filter magnet 46, mass analyzer 50, electrostatic lens 58, scan generator 70 and power supply 76. Additional features of control system 20 including measurer 22 and controller 24 will be further described in details below.

Although an exemplary ion implanter system 10 has been illustrated above, it should be understood by those skilled in the art that any now known or later developed system to generate and scan ion beam 4 may be used for the current invention. It is well known in the art how an ion beam 4 is generated by generating sub-system 2 and is scanned by scan sub-system 6. Therefore, description of those processes is not necessary for the understanding of the current invention. However, it should be understood that the current invention can be used with any now known or later developed process and methods of ion implantation.

3. Ion beam Profile Measurer

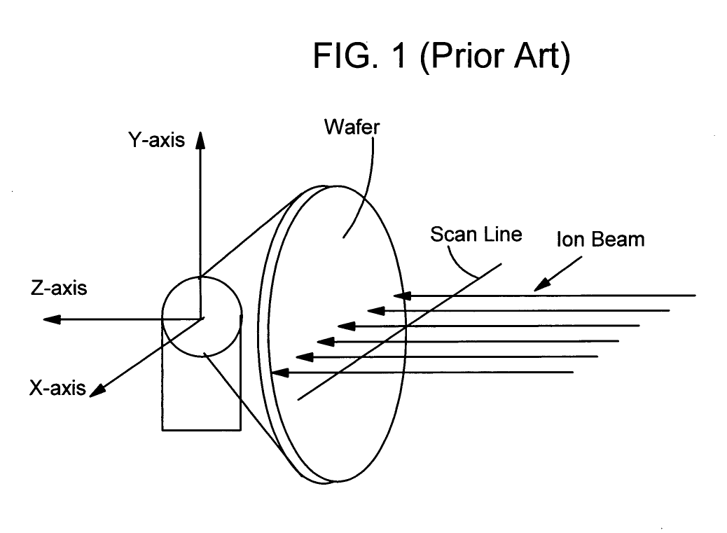

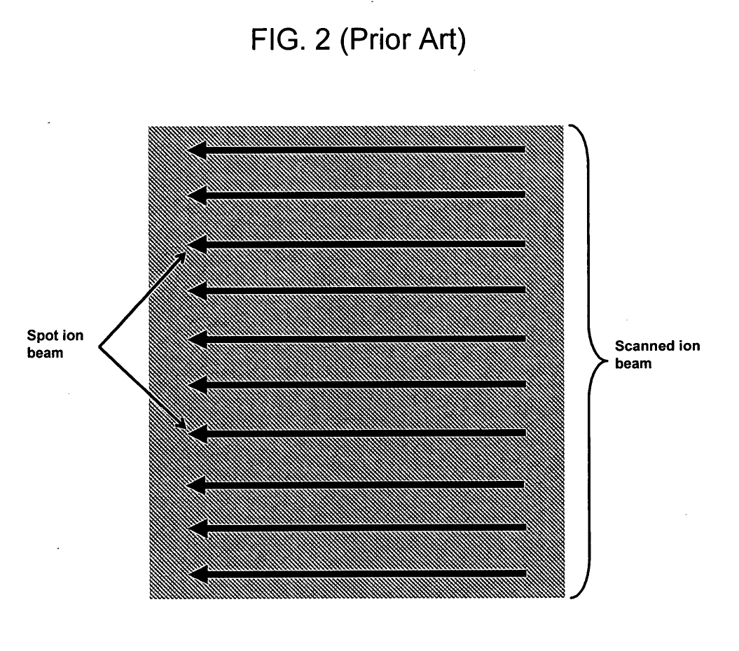

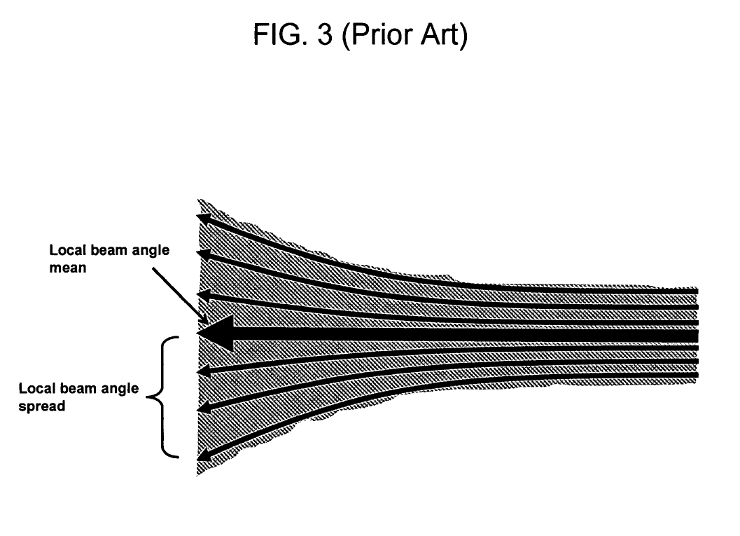

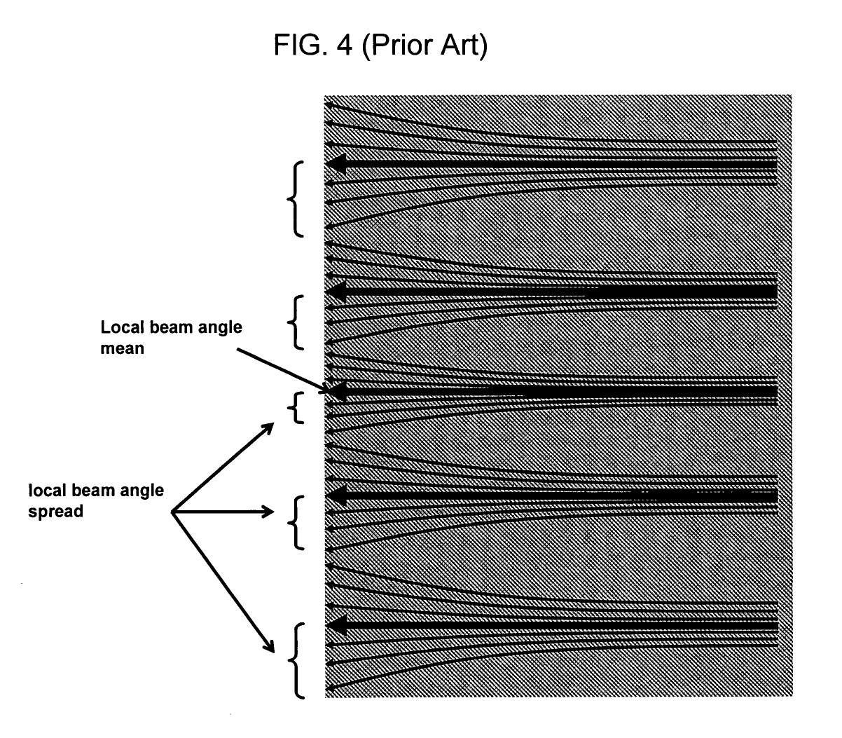

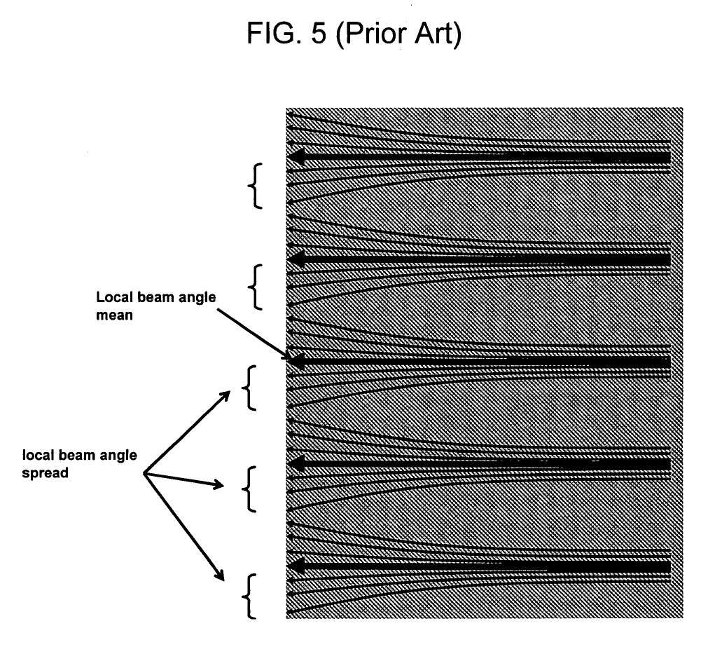

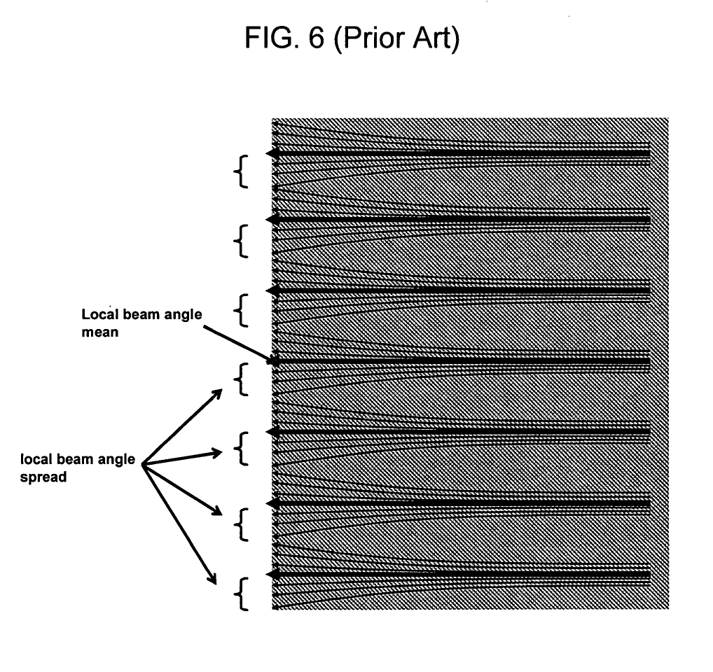

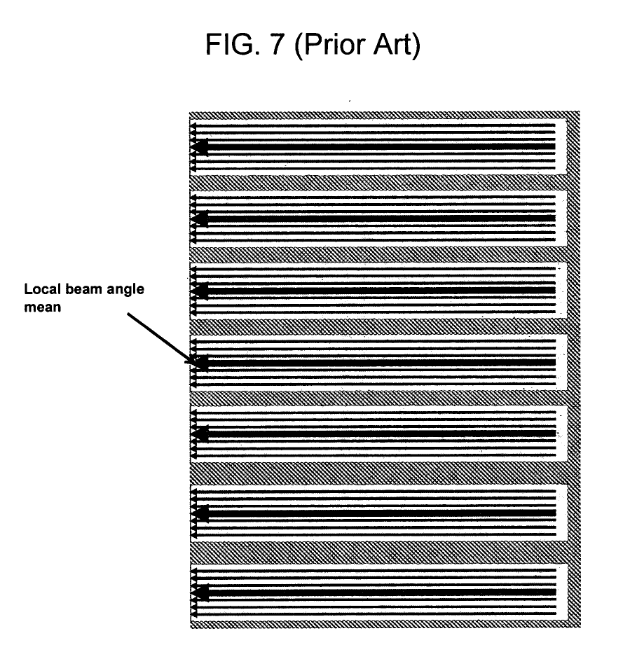

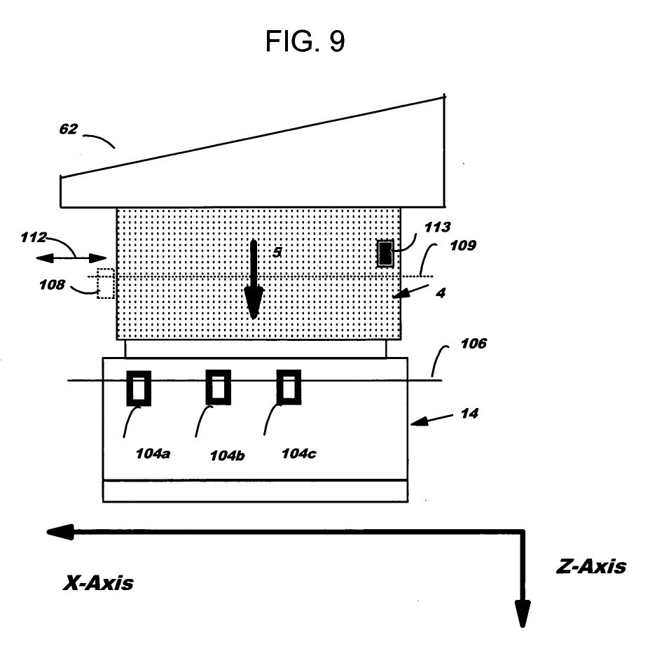

FIG. 9 shows a schematic view of an exemplary embodiment of measurer 22 within a scan plane, i.e., XZ-coordinate plane. (Please refer back to FIG. 1 for the description of a scan plane). As illustrated in FIG. 9, three sampling faraday cups 104a, 104b and 104c may be positioned at or near platen 14. Sampling faraday cups 104a-104c preferably are positioned in a lateral sampling line 106 substantially parallel to the X-Axis. That is, sampling line 106 is substantially parallel to the scan path (not shown) of ion beam 4. A desired direction 5 of ion beam 4 is parallel to the Z-Axis. That is, sampling line 106 is substantially perpendicular to desired direction 5. Measurer 22 also includes a traveling faraday cup 108. Traveling faraday cup 108 travels in a lateral traveling line 110 that is substantially parallel to sampling line 106, in a direction indicated by arrow 112. Traveling line 110 is located between sampling line 106 and angle corrector 62. Measurer 22 may also include a dose control faraday cup 113, which can be positioned at any location within a scan path of the ion beam 4 and between angle corrector 62 and platen 14.

Although an illustrative schematic embodiment of measurer 22 has been illustrated above, it should be understood by those skilled in the art that any now known or later developed system/or method to measure an ion beam profile may be used in the current invention and is within the scope of the current invention. For example, although the above described embodiment includes three sampling faraday cups 104, any number (n≧1) of sampling faraday cups can be used in a measurer of the current invention. Moreover, although the above described embodiment includes a traveling faraday cup 108, multiple (n≧1) stationary faraday cups can be positioned along traveling line 110 (or parallel to traveling line 110) to replace traveling faraday cup 108.

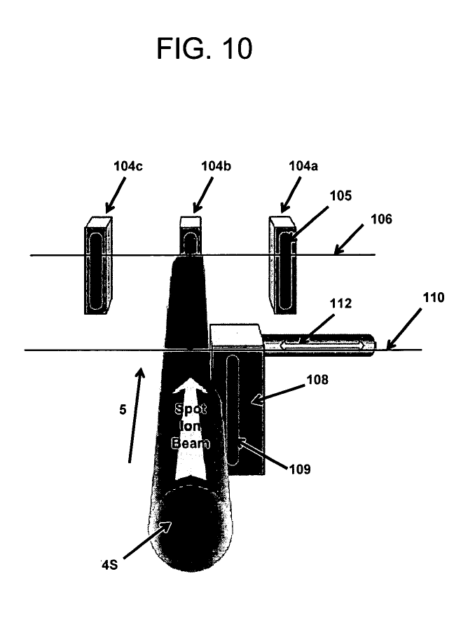

FIG. 10 shows a three-dimensional view of the illustrative embodiment of measurer 22 shown in FIG. 9. As shown in FIG. 10, three sampling faraday cups 104a, 104b and 104c are positioned in sampling line 106 and traveling faraday cup 108 travels along traveling line 110. A spot ion beam 4S of ion beam 4 hits sampling faraday cup 104b so that a profile of the spot ion beam 4S can be measured by sampling faraday cup 104b. As shown by FIG. 10, a profile of the spot ion beam 4S can also be measured by traveling faraday cup 108, if traveling faraday cup 108 travels across the spot ion beam 4S (or stops before sampling cups 104b in desired direction 5). Traveling faraday cup 108 and sampling faraday cups 104 each has an opening 109 and 105 respectively.

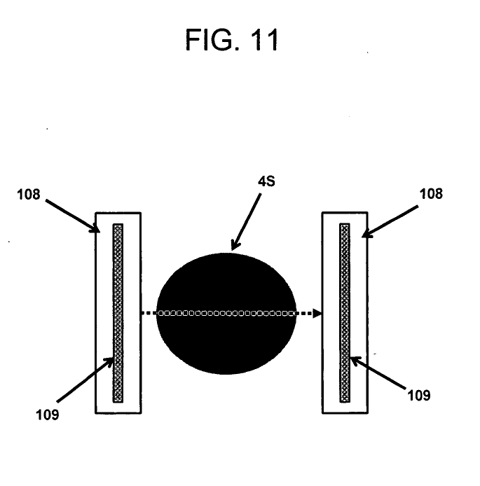

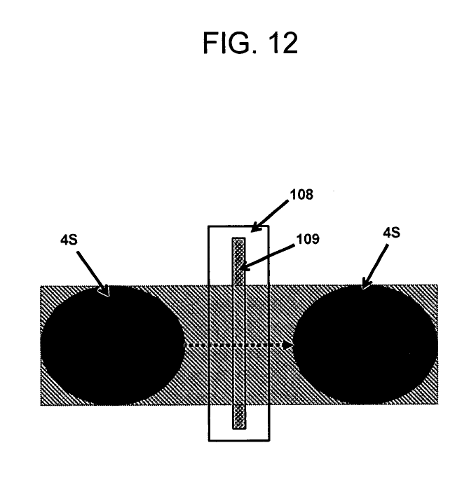

FIGS. 11-12 show two manners by which a traveling faraday cup 108 measures a profile of a spot ion beam 4S. In FIG. 11, traveling faraday cup 108 travels across a spot ion beam 4S. In FIG. 12, traveling faraday cup 108 is positioned in a predetermined position and spot ion beam 4S is slowly scanned across traveling faraday cup 108. In both manners, a profile of spot ion beam 4S is determined based on a traveling faraday cup current detected by traveling faraday cup 108 and a width of traveling faraday cup opening 109. Sampling faraday cups 104a, 104b and 104c can measure a profile of spot ion beam 4S using the manner shown in FIG. 12, i.e., by slowly scanning spot ion beam 4S across a sampling faraday cup 104. It is well known that at each specific time, an ion beam 4 constitutes only one spot ion beam. Therefore, it is understood that measuring a spot ion beam 4S is the same as measuring an ion beam 4.

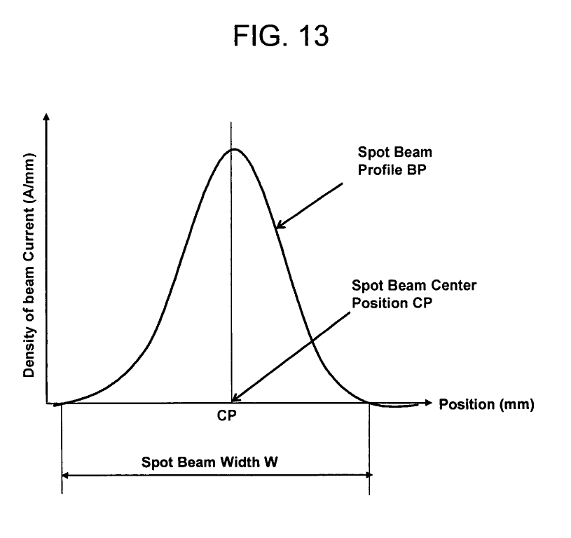

FIG. 13 shows an illustrative profile of a spot ion beam 4S. In FIG. 13, density of ion beam current (A/mm) is shown as a function of a lateral position along X-Axis (FIG. 1), hereinafter “position.” It should be recognized that density is measured in units of length, rather than area, because the measurement is made across a width interval of the spot ion beam. A spot ion beam center position (CP) is the position that corresponds to the horizontal geometry center of the area under the spot ion beam profile. Ion trajectories represented by the density of ion beam current corresponding to the center position strike a wafer in approximately the local ion beam angle mean of the spot ion beam 4S. A spot ion beam width (W) indicates a space between two positions that correspond to zero density of ion beam current, which corresponds to the local ion beam angle spread.

4. Controller

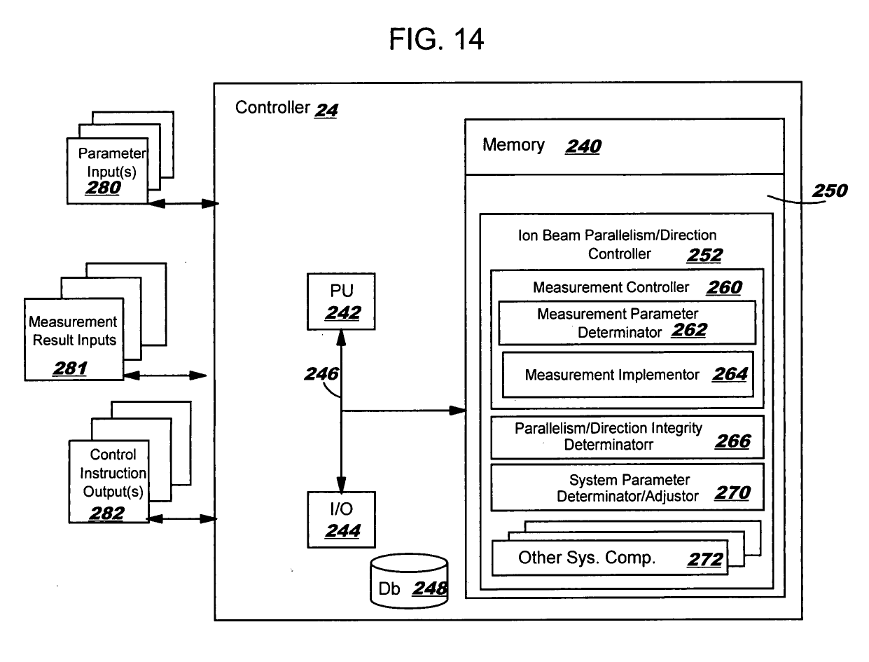

Referring to FIG. 14, a block diagram of an illustrative controller 24 is shown. Controller 24 includes a computer control system responsive to, inter alia, ion beam generating sub-system 2, ion beam scanning sub-system 6 and measurer 22. In one embodiment, controller 24 includes a memory 240, a processing unit (PU) 242, input/output devices (I/O) 244 and a bus 246. A database 248 may also be provided for storage of data relative to processing tasks. Memory 240 includes a program product 250 that, when executed by PU 240, comprises various functional capabilities described in further detail below. Memory 240 (and database 248) may comprise any known type of data storage system and/or transmission media, including magnetic media, optical media, random access memory (RAM), read only memory (ROM), a data object, etc. Moreover, memory 240 (and database 248) may reside at a single physical location comprising one or more types of data storage, or be distributed across a plurality of physical systems. PU 242 may likewise comprise a single processing unit, or a plurality of processing units distributed across one or more locations. I/O 244 may comprise any known type of input/output device including a network system, modem, keyboard, mouse, scanner, voice recognition system, CRT, printer, disc drives, etc. Additional components, such as cache memory, communication systems, system software, etc., may also be incorporated into controller 24.

As shown in FIG. 14, program product 250 may include an ion beam parallelism/direction controller 252 that includes a measurement controller 260 including a measurement parameter determinator 262 and a measurement implementer 264; a parallelism/direction integrity determinator 266; a system parameter determinator/adjuster 270; and other system components 272. Other system components 272 may include any now known or later developed parts of an ion implantation controller not individually delineated herein, but understood by those skilled in the art.

Referring to both FIG. 14 and FIG. 8, inputs to the controller 24 includes parameter inputs 280 and measurement result inputs 281. The parameter inputs 280 include those from a wide variety of the ion implanter system 10 components including ion generating sub-system 2, ion beam scanning sub-system 6, measurer 22, and user entered or other parameter inputs (FIG. 14). Parameter inputs 280 may indicate, among other things, particular states of ion implanter system 10 including measurer 22 and/or particular components thereof or may indicate user defined input parameters. That is, a parameter input 280 may be any characteristic of ion implanter system 10 including measurer 22, user defined constants or other variables that may affect operation of the system 10 including, in particular to the present invention, parallelism and direction of ion beam 4. Based on the above-described components of the measurer 22 (FIG. 9) used to measure a profile of ion beam 4, parameter inputs 280 may include, for example, desired direction 5 of ion beam 4, positions of sampling faraday cups 104 including lateral line 106, positions (traveling) of traveling faraday cup 108 including lateral line 110, width of the faraday cup openings 105 and 109, etc. Furthermore, based on the above-described components of ion implanter system 10, parameter inputs may include, for example, filter magnet 46 voltage, source dopant gas 40 flow rate, extraction manipulator 44 positioning (e.g., X, Y, Z axis), mass slit 54 aperture 56 opening, scan plates 66 and 68 spacing, scan generator 70 output (voltage, waveform, direct/alternative, etc), magnetic polepieces 72 spacing, power supply 76 output, target vertical scan system position 18 control setting and/or horizontal (XZ-coordinate plane) ion beam scan speed.

Measurement result inputs 281 include the results of the measurement by measurer 22. Control instructions 282 include the instructions to adjust the system parameters similar as those received at parameters inputs 280. It should be recognized that the above-described list is meant to be illustrative only. For example, it is common for a conventional controller to receive more than 5000 parameter inputs depending on the makeup of the ion implanter system used.

5. Ion beam Parallelism/Direction Controller

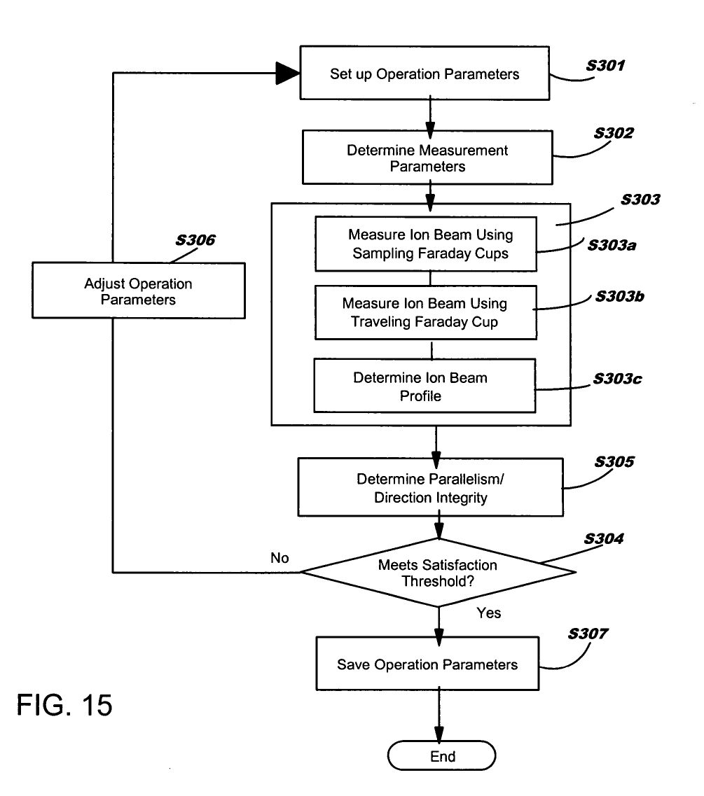

Ion beam parallelism/direction controller 252 functions generally to determine and control parallelism/direction of ion beam 4 including local parallelism and direction integrity. As is well known in the art, the parallelism and direction integrity problems of an ion beam 4 are more critical within the ion beam scan plane. Therefore, all the discussions that follow focus only on the scan plane, i.e., XZ-coordinate plane. One embodiment of operation of ion beam parallelism/direction controller 252 is shown in the flow diagram of FIG. 15. The illustrative embodiment of operation will be described with reference to FIGS. 8 and 14. In step S301, system parameter determinator/adjuster 270 sets up the operation parameters of the ion beam implanter system 10 (FIG. 8) including the ion beam generating sub-system 2 and the scanning sub-system 6, to generate, transmit and scan an ion beam 4 according to the requirements with respect to a specific target 12, including a desired direction 5 (FIG. 9) of ion beam 4. The actual ion beam 4 generated and scanned, however, may not be parallel and may be divergent to the desired direction 5.

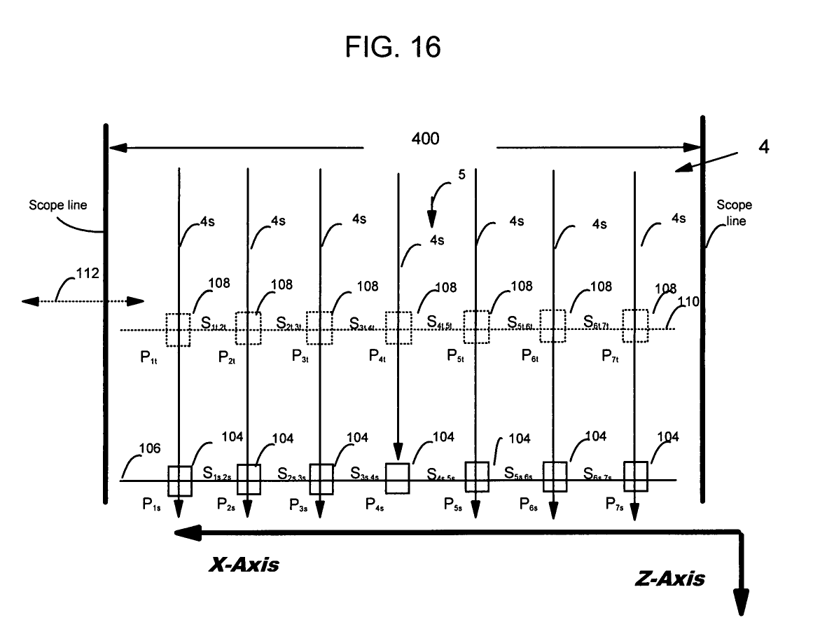

Next, in step S302, referring also to FIG. 9, the measurement parameter determinator 262 of the measurement controller 260 determines or obtains the pre-determined/known measurement parameters including, but not limited to, numbers and positions of sampling faraday cups 104, positions (stops) of traveling faraday cup 108, and a width of faraday cup openings (105 and 109 for sampling faraday cups 104 and traveling faraday cup 108, respectively) (FIG. 10). Preferably, a plurality (N≧2) of sampling faraday cups 104 are used in the measurement. FIG. 16 shows one embodiment of the numbers and positions of the sampling faraday cups 104 and the traveling faraday cup 108 stops. Please note, the FIG. 16 embodiment is similar to the FIG. 9 embodiment, so all the FIG. 9 descriptions apply to FIG. 16, except for the additional features described below with respect to FIG. 16 only. In FIG. 16, a plurality (here 7) of sampling faraday cups 104 (shown by solid squares) are located in a plurality (here 7) of positions (P₁ₛ-P₇ₛ) in a lateral sampling line 106 (shown by a solid line) horizontally across desired direction 5 (shown by arrow 5) of ion beam 4 and are located near or at platen 14 (not shown). Preferably, the spaces between every two immediately neighboring sampling faraday cups 104 (S_{1s.2s}-S_{6s.7s}) are the same (S). It should be understood that other arrangement of the positions of the sampling faraday cups 104 are also included in the current invention. For example, the spaces between every two immediately neighboring sampling faraday cups 104 (S_{1s.2s}-S_{6s.7s}) may not be the same.

Traveling faraday cup 108 (shown by dotted squares) travels along a lateral traveling line 110 (shown by a dotted line) that is parallel to sampling line 106. Arrow 112 shows the direction of traveling faraday cup 108 movements. Traveling line 110 is also horizontally across desired direction 5 of the ion beam 4. The stops (positions) of traveling faraday cup 108 along traveling line 110 are of the same number (here 7) as the number of sampling faraday cups 104 (here 7). That is, in the embodiment shown, traveling faraday cup 108 will stop at seven positions (P₁ₜ-P₇ₜ) in traveling line 110. Each of the stops (positions) of the traveling faraday cup 108 (P₁ₜ-P₇ₜ) corresponds to one of the sampling faraday cup positions (P₁ₛ-P₇ₛ) in desired direction 5 of the ion beam 4. Specifically, P₁ₜ corresponds to P₁ₛ; P₂ₜ corresponds to P₂ₛ; . . . and P₇ₜ corresponds to P₇ₛ. As a consequence, the spaces between every two immediately neighboring traveling faraday cup 108 positions (S_{1t.2t}-S_{6t.7t}) are the same as the spaces between the two corresponding sampling faraday cups 104 (S_{1s.2s}-S_{6s.7s}). In the embodiment shown, the spaces between every two immediately neighboring traveling faraday cup 108 positions are also the same as spacing S. However, it should be understood that the spaces between every two immediately neighboring traveling faraday cup 108 positions may not be the same where the spaces between every two immediately neighboring sampling faraday cups 104 (S_{1s.2s}-S_{6s.7s}) are not be the same.

In one embodiment, width of sampling faraday cup opening 105 (not shown in FIG. 16; please refer to FIG. 10) and width of traveling faraday cup opening 109 are set as the same. However, it should be understood that faraday cup opening width can be different, which only makes the subsequent determination more complicated, but does not affect the measurement.

Referring back to FIGS. 8, 14 and, in particular, 15, next in step S303, measurement implementer 264 of measurement controller 260 implements a measurement of an ion beam 4 profile. First, in step S303a, referring also to FIG. 16, measurement implementer 264 measures the ion beam 4 using sampling faraday cups 104. Specifically, measurement implementer 264 controls measurer 22 to move the traveling faraday cup 108 outside a measuring scope 400, which is defined by two scope lines that are horizontally parallel to desired direction 5 of ion beam 4 and each is beyond the outmost sampling faraday cup positions (P₁ₛ and P₇ₛ) by a distance of S (the space between two immediately neighboring sampling faraday cups). Still in step S303a, measurement implementer 264 then controls scan generator 70 to slowing scan an ion beam 4 across each of the seven sampling faraday cups 104 for each of them to detect a faraday cup current. As a consequence, each sampling faraday cup 104 measures a spot ion beam 4S. As will be described below, a spot ion beam profile can be determined based on the detected sampling faraday cup current and the width of the sampling faraday cup opening 105.

Still referring to FIGS. 15-16, next in step S303b, measurement implementer 264 measures the ion beam 4 using traveling faraday cup 108. Specifically, measurement implementer 264 controls measurer 22 to move traveling faraday cup 108 to position P₁ₜ and controls scan generator 70 to slowly scan an ion beam across traveling faraday cup 108 at the position P₁ₜ. Thus, traveling faraday cup 108 measures a spot ion beam 4S at P₁ₜ. Because the position P₁ₜ corresponds to the position P₁ₛ in desired direction 5 of ion beam 4, the traveling faraday cup 108 at position P₁ₜ measures the same spot ion beam 4S as the sampling faraday cup 104 at the position P₁ₛ measured in step 303a, as described above. Following the same procedure, the traveling faraday cup 108 measures spot ion beams 4S at positions P₂ₜ-P₇ₜ sequentially, which are the same spot ion beams as the sampling faraday cups 104 measured at positions P₂ₛ-P₇ₛ.

Although the embodiment described above uses a traveling faraday cup 108 to measure ion beam 4 at the positions P₁ₜ-P₇ₜ, it should be understood that any arrangements that can measure an ion beams are included in the current invention. For example, the traveling faraday cup 108 in the above embodiment can be replaced by seven sampling faraday cups located at the same positions P₁ₜ-P₇ₜ.

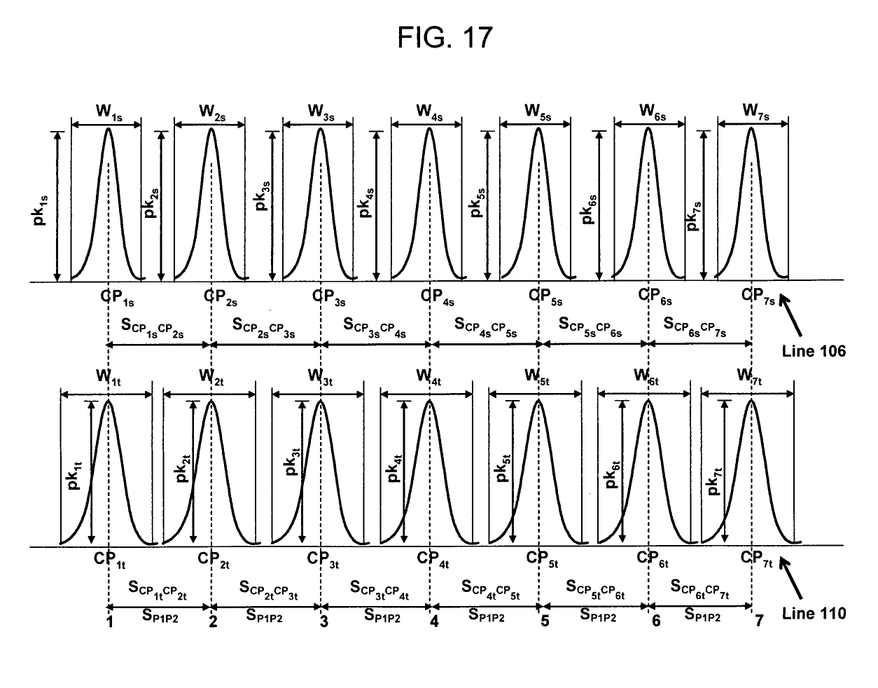

Still referring to FIGS. 15-16, next in step S303c, measurement implementer 264 determines ion beam 4 profiles based on the measurements of sampling faraday cups 104 and traveling faraday cup 108. As described before, an ion beam profile can be determined based on a faraday cup current detected and a width of the faraday cup opening. FIG. 17 shows an illustrative pair of ion beam (4) profiles that are measured by sampling faraday cups 104 in sampling line 106 (indicated as “line 106” or “line 106 profile”) and by traveling faraday cup 108 in traveling line 110 (indicated by “line 110” or “line 110 profile”). As shown in FIG. 17, the line 106 profile and the line 110 profile each includes seven spot ion beam profiles, which represent the separate measurements at positions P₁ₛ-P₇ₛ and positions P₁ₜ-P₇ₜ respectively. Each spot ion beam profile includes a spot ion beam width (W₁ₛ-W₇ₛ and W₁ₜ-W₇ₜ, respectively) and a spot ion beam center position (CP₁ₛ-CP₇ₛ and CP₁ₜ-CP₇ₜ, respectively). Each spot ion beam profile in the line 106 profile corresponds to one of the positions in sampling line 106 where spot ion beam 4S is measured by sampling faraday cup 104 at that position in sampling line 106. Each spot ion beam profile in the line 110 profile corresponds to one of the positions in traveling line 110 where the spot ion beam 4S is measured by traveling faraday cup 108 at that position. As described before regarding step S302 (FIG. 15), each traveling faraday cup 108 positions (P₁ₜ-P₇ₜ) corresponds to one sampling faraday cup 104 position (P₁ₛ-P₇ₛ), so each spot ion beam profile in line 110 profile corresponds to one spot ion beam profile the line 106 profile.

Referring back to FIG. 15, in step S304, parallelism/direction integrity determinator 266 (determinator 266) determines parallelism and/or direction integrity of ion beam 4 based on the ion beam profiles determined in step S303. The parallelism and/or direction integrity determination may include, but is not limited to, a global parallelism determination, a local parallelism determination, and a global/local direction determination. It should be understood that in step 304, determinator 266 may not perform all of the above mentioned determinations together. For example, determinator 266 may only perform global parallelism determination. Which determinations are made depends on the requirements of a specific ion implantation task or a setup requirement of ion implanter system 10. The specific determination mechanisms of determinator 266 can be described with reference to FIG. 17.

(a) Global Parallelism Determination

As defined above, a global parallelism of an ion beam is the relative degree of collimation of the ion beam, or a measure of convergence or divergence of two or more portions (spot ion beams) of a stationary or scanned ion beam. That is, a global parallelism refers to whether each spot ion beam 4S of ion beam 4 is parallel to each other. Also as discussed above, ion trajectories represented by the density of ion beam current corresponding to the center position of a spot ion beam 4S profile strike a wafer in approximately the local ion beam angle mean of the spot ion beam 4S. That is, ion trajectories represented by the center position of a spot ion beam 4S profile represent the direction of the spot ion beam 4S and can be used in assessing the global parallelism of ion beam 4. There are several possible embodiments to determine global parallelism according to the current invention.

Referring to FIGS. 16-17, in one embodiment, determinator 266 determines the spaces between the ion beam centers of the spot ion beam profiles of line 106 profile that immediately neighbor each other (Scp₁ₛ.cp₂ₛ to Scp₆ₛ.cp₇ₛ). Then, determinator 266 determines reference spaces between the immediately neighboring sampling faraday cup 104 positions that correspond to the line 106 spot ion beam profiles. The spaces between sampling faraday cup 104 positions (S_{1s.2s}-S_{6s.7s}) have already been determined (or known) by the measurement parameter determinator 262 in step S302 (FIG. 15). Here, determinator 266 obtains the predetermined (known) spaces between sampling faraday cup 104 positions (S_{1s.2s}-S_{6s.7s}), and matches them with the spaces between the immediately neighboring ion beam centers of the line 106 spot ion beam profiles (Scp₁ₛ.cp₂ₛ-Scp₆ₛ.cp₇ₛ). Specifically, S_{1s.2s} corresponds to Scp₁ₛ.cp₂ₛ; S_{2s.3s} corresponds to Scp₂ₛ.cp₃ₛ; . . . and S_{6s.7s} corresponds to Scp₆ₛ.cp₇ₛ. Then, determinator 266 compares the spaces Scp₁ₛ.cp₂ₛ-Scp₆ₛ.cp₇ₛ and the corresponding reference spaces S_{1s.2s}-S_{6s.7s} to determine parallelism and direction integrity of ion beam 4. Specifically, Scp₁ₛ.cp₂ₛ is compared to S_{1s.2s}; Scp₂ₛ.cp₃ₛ is compared to S_{2s.3s}; . . . and Scp₆ₛ.cp₇ₛ is compared to S_{6s.7s}. If each of the spaces Scp₁ₛ.cp₂ₛ to Scp₆ₛ.cp₇ₛ equal the corresponding reference spaces S_{1s.2s}-S_{6s.7s}, the local angle means of the spot ion beams measured by sampling faraday cups 104 are the same. In other words, the ion beam 4 is considered globally parallel.

Still referring to FIGS. 16-17, in another embodiment, determinator 266 determines first spaces between the ion beam centers of the spot ion beam profiles of the line 106 profile that immediately neighbor each other (Scp₁ₛ.cp₂ₛ to Scp₆ₛ.cp₇ₛ). Then, determinator 266 determines second spaces between the ion beam centers of the spot ion beam profiles of the line 110 profile that immediately neighbor each other (Scp₁ₜ.cp₂ₜ to Scp₆ₜ.cp₇ₜ). Because the line 106 and the line 110 profiles correspond to each other, the first spaces Scp₁ₛ.cp₂ₛ to Scp₆ₛ.cp₇ₛ correspond one-to-one to the second spaces Scp₁ₜ.cp₂ₜ to Scp₆ₜ.cp₇ₜ. Then, determinator 266 compares the first spaces Scp₁ₛ.cp₂ₛ to Scp₆ₛ.cp₇ₛ to the corresponding second spaces Scp₁ₜ.cp₂ₜ to Scp₆ₜ.cp₇ₜ. Specifically, Scp₁ₛ.cp₂ₛ is compared to Scp₁ₜ.cp₂ₜ; Scp₂ₛ.cp₃ₛ is compared to Scp₂ₜ.cp₃ₜ; . . . and Scp₆ₛ.cp₇ₛ is compared to Scp₆ₜ.cp₇ₜ. If each of the spaces Scp₁ₛ.cp₂ₛ to Scp₆ₛ.cp₇ₛ equals to the corresponding spaces Scp₁ₜ.cp₂ₜ to Scp₆ₜ.cp₇ₜ, the ion beam 4 is considered globally parallel.

In still another embodiment, determinator 266 compares the spaces between the every two immediately neighboring spot ion beam center positions of line 110 profile, i.e., Scp₁ₜ.cp₂ₜ to Scp₆ₜ.cp₇ₜ, to the spaces between the every two immediately neighboring traveling faraday cup 108 stops (positions) along traveling line 110, i.e., S_{1t.2t}-S_{6t.7t} (FIG. 16). If each of the spaces Scp₁ₜ-cp₂ₜ to Scp₆ₜ.cp₇ₜ equal the corresponding spaces S_{1t.2t}-S_{6t.7t}, ion beam 4 is considered globally parallel. However, this embodiment is inferior to the above two embodiments, because traveling line 110 (along which the traveling faraday cup 108 travels) is further away from platen 14 than sampling line 106. Thus, the line 110 profile and also spaces Scp₁ₜ.cp₂ₜ to Scp₆ₜ.cp₇ₜ are not as accurate as the line 106 profile and Scp₁ₛ.cp₂ₛ to Scp₆ₛ.cp₇ₛ in determining global parallelism.

(b) Ion Beam Direction Integrity Determination

Referring to FIGS. 16-17, determinator 266 may determine a direction of ion beam 4 in two stages. In the first stage, the determinator 266 determines whether the ion beam 4 is parallel to its desired direction 5. In one embodiment, determinator 266 determines line 106 divergence spaces between each spot ion beam center positions of the line 106 profile (CP₁ₛ-CP₇ₛ) and the corresponding sampling faraday cup 104 positions (P₁ₛ-P₇ₛ) (FIG. 16). Determinator 266 then determines line 110 divergence spaces between each spot ion beam center positions of the line 110 profile (CP₁ₜ-CP₇ₜ) and the corresponding traveling faraday cup 108 positions (P₁ₜ-P₇ₜ) (FIG. 16). It is understandable that each of the line 110 divergence spaces corresponds to one of the line 106 divergence spaces. Then, determinator 266 compares each of the line 110 divergence spaces to the corresponding one of the line 106 divergence spaces. If a line 110 divergence space equals to the corresponding line 106 divergence space, the related spot ion beam 4S is considered parallel to its desired direction 5 (FIG. 16), because a traveling faraday cup 108 position (P₁ₜ-P₇ₜ) and its corresponding sampling faraday cup 104 position (P₁ₛ-P₇ₛ) are both in desired direction 5 of ion beam 4 (FIG. 16). If all of the line 110 divergence spaces equal the corresponding line 106 divergence spaces, ion beam 4 is considered both globally parallel and in its desired direction 5 (FIG. 16).

According to the measurer embodiment of FIG. 16, desired direction 5 is substantially perpendicular to the traveling line 110 and the sampling line 106, and each traveling faraday cup 108 position (P₁ₜ-P₇ₜ) and its corresponding sampling faraday cup 104 position (Pₛ-P₇ₛ) are in the same lateral position. Therefore, determinator 266 can simplify the determination by simply comparing each spot ion beam center positions (CP) of the line 110 profile (CP₁ₜ-CP₇ₜ) with its corresponding spot ion beam center positions (CP) of the line 106 profile (CP₁ₛ-CP₇ₛ). If each line 110 spot ion beam center positions equal its corresponding line 106 spot ion beam center positions, ion beam 4 is considered both globally parallel and in its desired direction 5 (FIG. 16). It should be noted that, if ion beam 4 has already been determined globally parallel as described above, or has already been adjusted to be globally parallel, as discussed below, the parallelism of one spot ion beam 4S to desired direction 5 indicates the parallelism of the ion beam 4 to its desired direction 5 (FIG. 16).

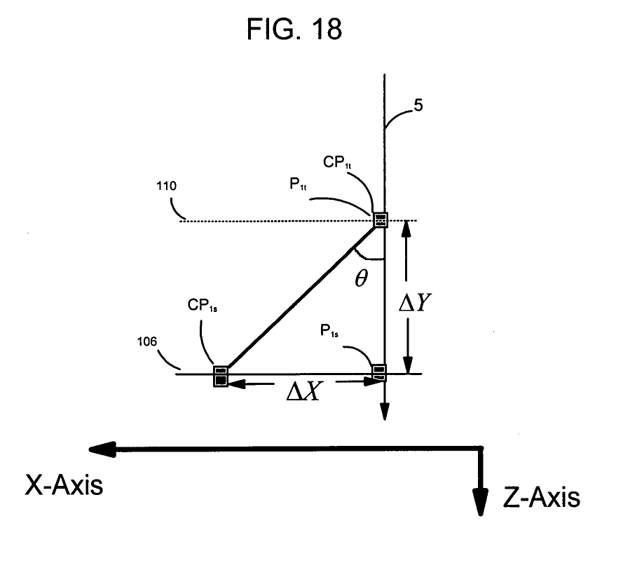

If a spot ion beam 4S is determined not parallel to its desired direction, determinator 266 may determine the divergence of the spot ion beam from its desired direction by calculating an angle between the spot ion beam and its desired direction (angle of incidence). Referring to FIG. 18, angle θ between a spot ion beam and its desired direction can be calculated by the following equation:
tan θ=Δx/Δy,
where Δx equals the difference between the spot ion beam center position in the line 106 profile and the spot ion beam center position in the line 110 profile (here, for example, CP₁ₛ and CP₁ₜ); and
Δy equals the distance between the line 106 and the line 110.
(c) Local Angle Distribution Uniformity and Local Parallelism Determination

Referring back to FIG. 17, determinator 266 determines a local angle distribution uniformity of the spot ion beams by comparing the seven spot ion beam profiles of the line 106 profile. The characteristics to be compared include the width of the spot ion beam profiles (W₁ₛ-W₇ₛ) and the value of the peak current measured by sampling faraday cups (PK₁ₛ-PK₇ₛ). Those two characteristics are related to each other. Specifically, for example, increases in the width usually mean decreases in the peak current. As described above with respect to FIG. 13, a spot ion beam width (W) indicates a space between two positions that correspond to zero density of ion beam current, which corresponds to the local ion beam angle spread. Thus, if all the spot ion beam profiles of the line 106 profile are substantially the same, the local angle distribution of ion beam 4 is considered uniform.

Still referring to FIG. 17, determinator 266 can also determine a local parallelism for each spot ion beam 4S. Specifically, in determining a local parallelism for a spot ion beam 4S, determinator 266 compares the line 106 spot ion beam profiles including spot ion beam width (W₁ₛ-W₇ₛ) and spot ion beam peak current (PK₁ₛ-PK₇ₛ) with the corresponding line 110 spot ion beam profiles. If the each of the line 106 spot ion beam profiles are substantially the same as its corresponding line 110 spot ion beam profile (spot ion beam width and spot ion beam peak current), the ion beam 4 is considered locally parallel.

In the determination embodiments described above, all the seven spot ion beam profiles of the line 106 and the line 110 profiles are used. However, it should be understood that any number of spot ion beam profiles can be used in the above described procedures. In addition, all the spaces in the above described embodiments are determined between two immediately neighboring positions. However, it should also be understood that a space between any two positions can be used in the above described procedures.

Referring back to FIG. 15, next in step S305, the results of the step S304 determinations are compared with a satisfaction threshold for a specific implantation work. The threshold can be generated automatically by controller 24 or by a user through a user interface (not shown) of input/output device 244 (FIG. 14). If the results of the step S304 determinations meet the satisfaction threshold, the system parameters are saved in step S307 and the operation ends. If the results do not meet the satisfaction threshold, in step S306, system parameter determinator/adjustor 270 adjusts the system parameters including, for example, those of the extraction manipulator 44, the filter magnet 46, the mass analyzer 50, the electrostatic lens 58, the scan generator 70 and the power supply 76 based on the determination results and reiterates the process again until determination results meet the satisfaction threshold.

6. Conclusion

In the previous discussion, it will be understood that the method steps discussed are performed by a processor, such as PU 242 of controller 24, executing instructions of program product 250 stored in a memory. It is understood that the various devices, modules, mechanisms and systems described herein may be realized in hardware, software, or a combination of hardware and software, and may be compartmentalized other than as shown. They may be implemented by any type of computer system or other apparatus adapted for carrying out the methods described herein. A typical combination of hardware and software could be a general-purpose computer system with a computer program that, when loaded and executed, controls the computer system such that it carries out the methods described herein. Alternatively, a specific use computer, containing specialized hardware for carrying out one or more of the functional tasks of the invention could be utilized. The present invention can also be embedded in a computer program product, which comprises all the features enabling the implementation of the methods and functions described herein, and which—when loaded in a computer system—is able to carry out these methods and functions. Computer program, software program, program, program product, or software, in the present context mean any expression, in any language, code or notation, of a set of instructions intended to cause a system having an information processing capability to perform a particular function either directly or after the following: (a) conversion to another language, code or notation; and/or (b) reproduction in a different material form.

While shown and described herein as a method, system and computer product for determining ion beam parallelism and direction integrity, it is understood that the invention further provides various alternative embodiments. For example, in another embodiment, the invention provides a business method that performs the process steps of the invention on a subscription, advertising, and/or fee basis. That is, a service provider, such as an Internet Service Provider, could offer to determine ion beam parallelism and direction integrity, as described above. In this case, the service provider can create, maintain, and support, etc., a computer infrastructure, such as a controller 24 (FIG. 14), that performs the process steps of the invention for one or more customers. In return, the service provider can receive payment from the customer(s) under a subscription and/or fee agreement and/or the service provider can receive payment from the sale of advertising space to one or more third parties.

In still another embodiment, the invention provides a method of generating a system for determining ion beam parallelism and direction integrity. In this case, a computer infrastructure, such as controller 24 (FIG. 14), can be obtained (e.g., created, maintained, having made available to, etc.) and one or more systems for performing the process steps of the invention can be obtained (e.g., created, purchased, used, modified, etc.) and deployed to the computer infrastructure. To this extent, the deployment of each system can comprise one or more of (1) installing program code on a computing device, such as controller 24 (FIG. 8), from a computer-readable medium; (2) adding one or more computing devices to the computer infrastructure; and (3) incorporating and/or modifying one or more existing systems of the computer infrastructure, to enable the computer infrastructure to perform the process steps of the invention.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A method for determining at least one of parallelism and direction integrity of an ion beam for implanting into a work piece, the method comprising steps of:
obtaining an ion beam profile at a plurality of positions in a lateral line across a desired direction of the ion beam; and
determining at least one of parallelism and direction integrity of the ion beam based on the ion beam profile and the plurality of positions.

2. The method of claim 1, further comprising adjusting the ion beam based on a result of the parallelism and direction integrity determining step, wherein the ion beam adjusting includes at least one of the following:
adjusting the ion beam to be globally parallel;
adjusting the ion beam to be parallel to the desired direction;
adjusting the ion beam to have a substantially same local angle distribution; and
adjusting the ion beam to be locally parallel.

3. The method of claim 1, wherein the ion beam profile includes a plurality of spot ion beam profiles and each of the plurality of spot ion beam profiles corresponds to one of the plurality of positions, and each spot ion beam profile includes an ion beam center and an ion beam width.

4. The method of claim 3, wherein the parallelism and direction integrity determining step includes:
determining a target space between the ion beam centers of at least two of the plurality of spot ion beam profiles;
determining a reference space between the positions that correspond to the at least two of the plurality of spot ion beam profiles; and
comparing the target space and the reference space to determine parallelism of the ion beam.

5. The method of claim 3, further comprising controlling a spot ion beam local angle distribution by adjusting the ion beam so that the plurality of spot ion beam profiles are substantially the same.

6. The method of claim 3, wherein:
the obtaining step includes obtaining a first ion beam profile including a first set of spot ion beam profiles at a first set of positions in a first lateral line across the desired direction of the ion beam and obtaining a second ion beam profile including a second set of spot ion beam profiles at a second set of positions in a second different lateral line across the desired direction of the ion beam, each of the second set of positions corresponding to a lateral position of one of the first set of positions and each of the second set of spot ion beam profiles corresponding to one of the first set of spot ion beam profiles; and
the determining step includes determining the parallelism and direction integrity of the ion beam based on the first ion beam profile, the second ion beam profile, the first set of positions, and the second set of positions.

7. The method of claim 6, further comprising steps of:
determining a first space between the ion beam centers of at least two of the first set of spot ion beam profiles;
determining a second space between the ion beam centers of the second set of spot ion beam profiles that correspond to the at least two of the first set of spot ion beam profiles; and
comparing the first space and the second space to determine parallelism.

8. The method of claim 6, further comprising steps of:
determining a first space between the ion beam center of one of the first set of spot ion beam profiles and the corresponding one of the first set of positions;
determining a second space between the ion beam center of one of the second set of spot ion beam profiles that corresponds to the one of the first set of spot ion beam profiles and one of the second set of positions that corresponds to the one of the second set of spot ion beam profiles; and
comparing the first space and the second space to determine parallelism and direction integrity of the ion beam.

9. The method of claim 6, further comprising adjusting the ion beam to be locally parallel by making the first ion beam profile substantially the same as the second ion beam profile.

10. A system for determining at least one of parallelism and direction integrity of an ion beam for implanting into a work piece, the system comprising:
a measurer for obtaining an ion beam profile at a plurality of positions in a lateral line across a desired direction of the ion beam; and
a determinator for determining at least one of parallelism and direction integrity of the ion beam based on the ion beam profile and the plurality of positions.

11. The system of claim 10, further comprising a controller for adjusting the ion beam based on a result of the parallelism and direction integrity determination, wherein the ion beam adjusting includes at least one of the following:
adjusting the ion beam to be globally parallel;
adjusting the ion beam to be parallel to the desired direction;
adjusting the ion beam to have a substantially same local angle distribution; and
adjusting the ion beam to be locally parallel.

12. The system of claim 10, wherein the ion beam profile includes a plurality of spot ion beam profiles and each of the plurality of spot ion beam profiles corresponds to one of the plurality of positions, and each spot ion beam profile includes an ion beam center and an ion beam width, and the determinator is further configured to determine at least one of parallelism and direction integrity based on the ion beam center, ion beam width and the plurality of positions.

13. The system of claim 12, wherein the determinator is further configured to:
determine a target space between the ion beam centers of at least two of the plurality of spot ion beam profiles;
determine a reference space between the positions that correspond to the at least two of the plurality of spot ion beam profiles; and
compare the target space and the reference space to determine parallelism of the ion beam.

14. The system of claim 12, wherein the controller is further configured to control a spot ion beam local angle distribution by adjusting the ion beam so that the plurality of spot ion beam profiles are substantially the same.

15. The system of claim 12, wherein:
the plurality of positions include a first set of positions in a first lateral line across the desired direction of the ion beam and a second set of positions in a second different lateral line across the desired direction of the ion beam, each of the second set of positions corresponding to a lateral position of one of the first set of positions;
the measurer is further configured to obtain a first ion beam profile including a first set of spot ion beam profiles at the first set of positions and obtain a second ion beam profile including a second set of spot ion beam profiles at the second set of positions, each of the second set of spot ion beam profiles corresponding to one of the first set of spot ion beam profiles; and
the determinator is further configured to determine parallelism and direction integrity of the ion beam based on the first ion beam profile, the second ion beam profile, the first set of positions, and the second set of positions.

16. A program product stored on a computer-readable medium, which when executed, enables a computer infrastructure to determine at least one of parallelism and direction integrity of an ion beam for implanting into a work piece, the program product comprising computer program code for enabling the computer infrastructure to:
obtain an ion beam profile at a plurality of positions in a lateral line across a desired direction of the ion beam; and
determine at least one of parallelism and direction integrity of the ion beam based on the ion beam profile and the plurality of positions.

17. The program product of claim 16, further comprising computer program code for enabling the computer infrastructure to adjust the ion beam based on a result of the parallelism and direction integrity determination, wherein the ion beam adjusting includes at least one of the following:
adjusting the ion beam to be globally parallel;
adjusting the ion beam to be parallel to the desired direction;
adjusting the ion beam to have a substantially same local angle distribution; and
adjusting the ion beam to be locally parallel.

18. The program product of claim 16, wherein the ion beam profile includes a plurality of spot ion beam profiles and each of the plurality of spot ion beam profiles corresponds to one of the plurality of positions, and each spot ion beam profile includes an ion beam center and an ion beam width.

19. The program product of claim 18, further comprising computer program code for enabling the computer infrastructure to:
determine a target space between ion beam centers of at least two of the plurality of spot ion beam profiles;
determine a reference space between the positions that correspond to the at least two of the plurality of spot ion beam profiles; and
compare the target space and the reference space to determine parallelism of the ion beam.

20. The program product of claim 18, further comprising computer program code for enabling the computer infrastructure to control a spot ion beam local angle distribution by adjusting the ion beam so that the plurality of spot ion beam profiles are substantially the same.

21. The program product of claim 18, further comprising computer program code for enabling the computer infrastructure to:
obtain a first ion beam profile including a first set of spot ion beam profiles at a first set of positions in a first lateral line across the desired direction of the ion beam and obtain a second ion beam profile including a second set of spot ion beam profiles at a second set of positions in a second different lateral line across the desired direction of the ion beam, each of the second set of positions corresponding to a lateral position of one of the first set of positions and each of the second set of spot ion beam profiles corresponding to one of the first set of spot ion beam profiles; and
determine parallelism and direction integrity of the ion beam based on the first ion beam profile, the second ion beam profile, the first set of positions, and the second set of positions.

22. The program product of claim 21, further comprising computer program code for enabling the computer infrastructure to:
determine a first space between the ion beam center of one of the first set of spot ion beam profiles and the corresponding one of the first set of positions;
determine a second space between the ion beam center of one of the second set of spot ion beam profiles that corresponds to the one of the first set of spot ion beam profiles and one of the second set of positions that corresponds to the one of the second set of spot ion beam profiles; and
compare the first space and the second space to determine parallelism of the ion beam.

23. The program product of claim 21, further comprising computer program code for enabling the computer infrastructure to adjust the ion beam to be locally parallel by making the first ion beam profile substantially the same as the second ion beam profile.

24. A method of generating a system for determining at least one of parallelism and direction integrity of an ion beam for implanting into a work piece, the method comprising providing a computer infrastructure operable to:
obtain an ion beam profile at a plurality of positions in a lateral line across a desired direction of the ion beam; and
determine at least one of parallelism and direction integrity of the ion beam based on the ion beam profile and the plurality of positions.

25. The method of claim 24, wherein the computer infrastructure is further operable to adjust the ion beam based on a result of the parallelism and direction integrity determination, wherein the ion beam adjusting includes at least one of the following:
adjusting the ion beam to be globally parallel;
adjusting the ion beam to be parallel to the desired direction;
adjusting the ion beam to have a substantially same local angle distribution; and
adjusting the ion beam to be locally parallel.

26. The method of claim 24, wherein the ion beam profile includes a plurality of spot ion beam profiles and each of the plurality of spot ion beam profiles corresponds to one of the plurality of positions, and each spot ion beam profile includes an ion beam center and an ion beam width.

27. The method of claim 26, wherein the computer infrastructure is further operable to:
determine a target space between ion beam centers of at least two of the plurality of spot ion beam profiles;
determine a reference space between the positions that correspond to the at least two of the plurality of spot ion beam profiles; and
compare the target space and the reference space to determine parallelism of the ion beam.

28. The method of claim 26, wherein the computer infrastructure is further operable to control a spot ion beam local angle distribution by adjusting the ion beam so that the plurality of spot ion beam profiles are substantially the same.
